(19) United States
(12) Patent Application Publication
(10) Pub. No.: US 2025/0311456 A1
(43) Pub. Date: Oct. 2, 2025

(54) SEMICONDUCTOR PACKAGE

(71) Applicant: SAMSUNG ELECTRONICS CO., LTD., Suwon-si (KR)

(72) Inventors: Tsuyoshi OGAWA, Yokohama-si (JP); Koji HAMAGUCHI, Yokohama-si (JP); Kazutaka HONDA, Yokohama-si (JP); Kosuke HAREYAMA, Yokohama-si (JP)

(73) Assignee: SAMSUNG ELECTRONICS CO., LTD., Suwon-si (KR)

(21) Appl. No.: 19/098,209

(22) Filed: Apr. 2, 2025

(30) Foreign Application Priority Data
Apr. 2, 2024 (JP) 2024-059327
Dec. 31, 2024 (KR) 10-2024-0202664

(51) Int. Cl. H10F 39/00

(52) U.S. Cl. CPC H10F 39/804; H10F 39/811; H10F 39/024

(57) ABSTRACT

A semiconductor package may include: a semiconductor chip including an electrode on a first surface, which is a light incident surface, of a substrate; a through hole extending from a second surface of the substrate, which is opposite to the first surface of the substrate, to the electrode; a wiring layer on the second surface and electrically connected to the electrode through the through hole; a pillar electrode electrically connected to the wiring layer; a first conductor between the pillar electrode and the wiring layer; and a resin layer on a side surface of the pillar electrode and a side surface of the first conductor. A second end portion of the pillar electrode, which is opposite to a first end portion and contacts the first conductor, may be exposed from the resin layer.

### CROSS-REFERENCE TO RELATED APPLICATIONS

This application claims the benefits of Japanese Patent Application No. 2024-059327, filed on Apr. 2, 2024, in the Japan Patent Office, and Korean Patent Application No. 10-2024-0202664, filed on Dec. 31, 2024, in the Korean Intellectual Property Office, the disclosures of which are incorporated herein in their entireties by reference.

### BACKGROUND

### 1. Field

The disclosure relates to a semiconductor package, and more particularly, to a semiconductor package including a connection terminal part.

### 2. Description of Related Art

Recently, as semiconductor chips are miniaturized and highly integrated, semiconductor packages are manufactured as a chip scale package (CSP), and package mounting of a flip chip type is being used.

In CSPs, because a package size is the same as a size of a semiconductor chip, a size is small, and the productivity of a wafer level process is good, but there is a problem where the solder connection reliability of package mounting is low.

In package mounting of CSPs, the reason that solder connection reliability is low may be an increase in stress applied to a connection terminal part and a periphery thereof due to a thermal expansion difference on a temperature change of a temperature cycle because a difference between a coefficient of linear expansion of silicon configuring a chip substrate in a semiconductor chip which is a mother body of a CSP and a coefficient of linear expansion of a mounting substrate such as a mother board is large.

### SUMMARY

The disclosure provides a semiconductor package which may reduce stress occurring in a connection terminal part due to a temperature change in package mounting and may thus increase the connection reliability of the connection terminal part.

According to an aspect of the disclosure, a semiconductor package may include: a semiconductor chip including an electrode on a first surface, which is a light incident surface, of a substrate; a through hole extending from a second surface of the substrate, which is opposite to the first surface of the substrate, to the electrode; a wiring layer on the second surface and electrically connected to the electrode through the through hole; a pillar electrode electrically connected to the wiring layer; a first conductor between the pillar electrode and the wiring layer; and a resin layer on a side surface of the pillar electrode and a side surface of the first conductor. A second end portion of the pillar electrode, which is opposite to a first end portion of the pillar electrode contacting the first conductor, may be exposed from the resin layer.

According to an aspect of the disclosure, a semiconductor package may include: a semiconductor chip including a substrate including: a first surface; a second surface opposite to the first surface; and an electrode on the first surface. The semiconductor package may further include: a through hole extending from the second surface to the electrode; a wiring layer on the second surface, in the through hole, and electrically connected to the electrode; a first conductor on the wiring layer; a pillar electrode on the first conductor and electrically connected to the wiring layer; and a resin layer on the second surface of the substrate and around a side surface of the first conductor and a side surface of the pillar electrode. A coefficient of linear expansion of the resin layer is greater than or equal to a coefficient of linear expansion of the substrate.

According to an aspect of the disclosure, a semiconductor package may include: a transparent substrate; and a semiconductor chip including a substrate including: a first surface facing the transparent substrate; a second surface opposite to the first surface; and an electrode on the first surface. The semiconductor package may further include: a through hole extending from the second surface to the electrode; a wiring layer on the second surface, in the through hole, and electrically connected to the electrode; a first conductor on the wiring layer; a pillar electrode on the first conductor and electrically connected to the wiring layer; a resin layer on the second surface of the substrate of the semiconductor chip and around a side surface of the first conductor and a side surface of the pillar electrode; and a connection terminal on a second end portion of the pillar electrode, opposite to a first end portion of the pillar electrode contacting the first conductor, wherein an elastic modulus of the first conductor is lower than an elastic modulus of the pillar electrode.

### BRIEF DESCRIPTION OF THE DRAWINGS

Embodiments will be more clearly understood from the following detailed description taken in conjunction with the accompanying drawings in which:

FIG. 1 is a cross-sectional view schematically illustrating a state where a semiconductor package according to one or more embodiments is mounted on a mounting substrate;

FIG. 2 is a cross-sectional view schematically illustrating a semiconductor package according to one or more embodiments;

FIG. 3A is a cross-sectional view schematically illustrating a method of manufacturing a semiconductor package, according to one or more embodiments;

FIG. 3B is a cross-sectional view schematically illustrating a method of manufacturing a semiconductor package, according to one or more embodiments;

FIG. 3C is a cross-sectional view schematically illustrating a method of manufacturing a semiconductor package, according to one or more embodiments;

FIG. 3D is a cross-sectional view schematically illustrating a method of manufacturing a semiconductor package, according to one or more embodiments;

FIG. 3E is a cross-sectional view schematically illustrating a method of manufacturing a semiconductor package, according to one or more embodiments;

FIG. 3F is a cross-sectional view schematically illustrating a method of manufacturing a semiconductor package, according to one or more embodiments;

FIG. 3G is a cross-sectional view schematically illustrating a method of manufacturing a semiconductor package, according to one or more embodiments;

FIG. 3H is a cross-sectional view schematically illustrating a method of manufacturing a semiconductor package, according to one or more embodiments;

FIG. 3I is a cross-sectional view schematically illustrating a method of manufacturing a semiconductor package, according to one or more embodiments;

FIG. 3J is a cross-sectional view schematically illustrating a method of manufacturing a semiconductor package, according to one or more embodiments;

FIG. 3K is a cross-sectional view schematically illustrating a method of manufacturing a semiconductor package, according to one or more embodiments;

FIG. 3L is a cross-sectional view schematically illustrating a method of manufacturing a semiconductor package, according to one or more embodiments;

FIG. 3M is a cross-sectional view schematically illustrating a semiconductor package manufactured by a method of manufacturing a semiconductor package, according to one or more embodiments;

FIG. 4 is a cross-sectional view schematically illustrating a semiconductor package according to embodiments;

FIG. 5A is a cross-sectional view schematically illustrating a semiconductor package according to embodiments;

FIG. 5B is a cross-sectional view schematically illustrating a semiconductor package according to embodiments; and

FIG. 6 is a graph showing a result of a solder lifetime simulation of each of one or more embodiments and a comparative example.

### DETAILED DESCRIPTION

Hereinafter, embodiments will be described in detail with reference to the accompanying drawings. In the drawings, like reference numeral refers to like element, and a size of each element is illustrated at a ratio differing from one or more embodiments, for clarity and convenience of description. One or more embodiments described below is merely one or more embodiments, and various modifications may be implemented from the embodiment.

Hereinafter, being described as “on” or “over” may include being on not to contact as well as being just on to contact. Likewise, being described as “under” or “below” may include being under not to contact as well as being just under to contact.

A singular form of elements may include a plural form unless another case is clearly designated in context. Also, when an arbitrary portion includes or has an arbitrary element, this may denote further including another element instead of excluding another element, unless oppositely described.

An order may be clearly described on operations configuring a method, or unless oppositely described, the operations may be performed in an appropriate order. The disclosure is not limited to the description order of the operations. The use of all examples or terms may be merely for describing the disclosure, and unless defined by claims, the spirit scope is not limited by the examples or the terms.

In the following description, in a case where description is given with ordinal numerals such as “first” and “second”, and unless specially described, the ordinal numerals are used for convenience and do not define an arbitrary order.

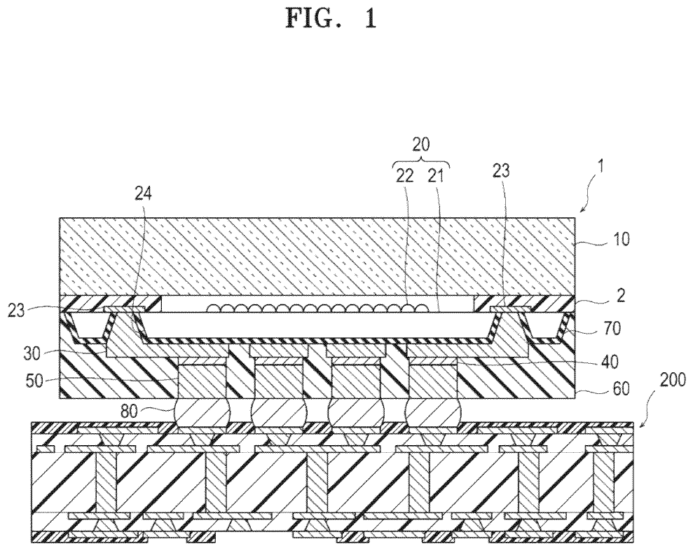

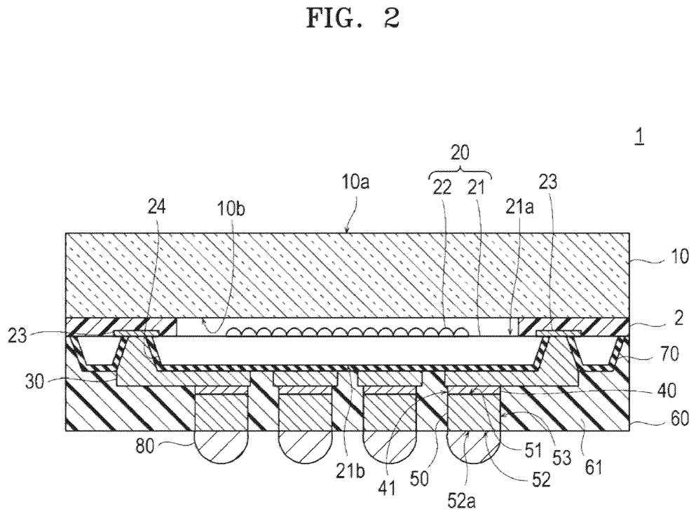

FIG. 1 is a cross-sectional view schematically illustrating a state where a semiconductor package 1 according to one or more embodiments is mounted on a mounting substrate 200. FIG. 2 is a cross-sectional view schematically illustrating the semiconductor package 1 according to one or more embodiments.

The semiconductor package 1 according to one or more embodiments may be described with reference to FIGS. 1 and 2. As illustrated in FIGS. 1 and 2, the semiconductor package 1 may be a chip scale package (CSP) where a semiconductor chip 20 is configured with a solid-state imaging device (a complementary metal oxide semiconductor (CMOS) image sensor).

The semiconductor package 1 may include a transparent substrate 10, a semiconductor chip 20, a wiring layer 30, a first conductive part 40 (first conductor), a pillar electrode 50, and an encapsulation resin layer 60. The semiconductor package 1 may be mounted on the mounting substrate 200 through a connection terminal part 80.

The transparent substrate 10 may include, for example, a transparent material having light transmissive properties such as a resin material such as a glass material or polyimide. A planar size of the transparent substrate 10 may have a size which is greater than or equal to a planar size of a chip substrate 21 of the semiconductor chip 20.

The transparent substrate 10 may include a first surface 10a which is an incident surface for light and a second surface 10b which is opposite to the first surface 10a. In a state where the second surface 10b of the transparent substrate 10 faces a first surface 21a of the chip substrate 21 of the semiconductor chip 20, the transparent substrate 10 may be bonded to the semiconductor chip 20 through a bonding part 2 including an encapsulant (a DAM agent). With respect to FIG. 1, the first surface 10a of the transparent substrate 10 may be an upper surface of the transparent substrate 10, and the second surface 10b of the transparent substrate 10 may be a lower surface of the transparent substrate 10.

The semiconductor chip 20 may include the chip substrate 21 including silicon or the like. An integrated circuit (IC) circuit pattern may be formed on the first surface 21a of the chip substrate 21. With respect to FIG. 2, the first surface 21a of the chip substrate 21 of the semiconductor chip 20 may be an upper surface (an incident surface) of the chip substrate 21, and the second surface 21b of the chip substrate 21 may be a lower surface of the chip substrate 21.

The semiconductor chip 20 may include a light receiving region where a plurality of pixels converting incident light into an electrical signal are vertically and horizontally arranged in a column form and may be configured with a CMOS image sensor on which a color filter, a photodiode, and a pixel circuit are mounted, in addition to a microlens (an on chip lens) 22.

An electrode 23 may be formed on the first surface 21a of the semiconductor chip 20. A through hole (via) 24 may be formed up to the electrode 23 from the second surface 21b of the chip substrate 21 so as to be electrically connected to the electrode 23. For example, the through hole 24 may extend in a vertical direction toward the electrode 23 from the second surface 21b of the chip substrate 21. For example, the through hole 24 may be formed by a processing process such as deep reactive ion etching (DRIE).

An insulation layer 70 may be formed on the second surface 21b of the chip substrate 21 of the semiconductor chip 20, a side surface of the chip substrate 21, and a side surface of the through hole 24. The insulation layer 70 may be formed by a thin film formation process such as a deposition process, a sputtering process, and a chemical mechanical deposition or chemical vapor deposition (CVD) process. A portion, formed in a surface which at least corresponds to a bottom portion of the through hole 24 (i.e., which is opposite to the electrode 23), of the insulation layer 70 may be removed.

The wiring layer 30 may be stacked and formed on the insulation layer 70. The wiring layer 30 may be formed by stacking a metal material, such as copper (Cu), aluminum (Al), or gold (Au), as a single layer or a multilayer. The wiring layer 30 may be formed by a wiring formation process such as a photolithography process.

The first conductive part 40 may be stacked and formed on the wiring layer 30. The first conductive part 40 may be disposed between the pillar electrode 50 and the wiring layer 30 and may electrically connect the pillar electrode 50 to the wiring layer 30. The first conductive part 40 may include a solder or a conductive paste such as a conductive adhesive including a copper particle. The first conductive part 40 may be formed by a printing process such as a screen printing process or an inkjet printing process.

An elastic modulus of the first conductive part 40 may be lower than that of the pillar electrode 50. For example, a magnitude relationship of an elastic modulus between the first conductive part 40 and the pillar electrode 50 may satisfy a relationship of —an elastic modulus of the first conductive part 40<an elastic modulus of the pillar electrode 50—. The semiconductor package 1 may include the first conductive part 40 which is disposed between the wiring layer 30 and the pillar electrode 50 and has an elastic modulus which is lower than that of the pillar electrode 50, and thus, may effectively reduce stress applied to the connection terminal part 80 due to a thermal expansion difference.

The pillar electrode 50 may be stacked and formed on the first conductive part 40. The pillar electrode 50 may be disposed on the first conductive part 40. The pillar electrode 50 may be an electrode member which includes a first end portion 51 connected to the first conductive part 40, a second end portion 52 which is an end portion opposite to the first end portion 51 in an axial direction and where the connection terminal part 80 is formed, and a side surface 53 which connects the first end portion 51 to the second end portion 52.

In some embodiments, the pillar electrode 50 may be configured with a metal pin (a copper pin) including copper as a main component and a member where copper plating formed by a known plating process such as an electroplating process or chemical plating is provided in a pillar shape. For example, because the pillar electrode 50 uses a copper pin, the pillar electrode 50 may be formed by merely placing a metal pin, functioning as an electrode, at a formation position of the first conductive part 40, and thus, assembling performance in manufacturing may be enhanced.

The encapsulation resin layer 60 may be formed to at least cover a side surface of the first conductive part 40 and a side surface of the pillar electrode 50. For example, as illustrated in FIG. 2, the encapsulation resin layer 60 may be formed to cover the wiring layer 30 and allow the second end portion 52 of the pillar electrode 50 to be exposed at the outside.

For example, the second end portion 52 may be aligned with a lower surface of the encapsulation resin layer 60 in a horizontal direction. For example, a surface, aligned with the lower surface of the encapsulation resin layer 60 in the horizontal direction, of the second end portion 52 may be an exposure surface 52a of the second end portion 52 exposed at the outside. In some embodiments, the connection terminal part 80 may be formed on the exposure surface 52a of the second end portion 52.

The encapsulation resin layer 60 may include resin, having insulating properties, such as epoxy resin capable of being applied as potting resin. For example, the encapsulation resin layer 60 may include a nonconductive filler such as an inorganic filler having a flat shape or silica having a spherical shape. The nonconductive filler of the encapsulation resin layer 60 may be adjusted in content, so as to increase the connection reliability of the connection terminal part 80 of the semiconductor package 1.

A content of filler of the encapsulation resin layer 60 may be adjusted, and thus, a coefficient of linear expansion or an elastic modulus of the encapsulation resin layer 60 may be adjusted. Accordingly, the semiconductor package 1 may include the encapsulation resin layer 60 where a content of filler has been adjusted to increase the connection reliability of the connection terminal part 80, and thus, may be a package where the connection reliability of the connection terminal part 80 is good.

The encapsulation resin layer 60 may have a coefficient of linear expansion which is greater than or equal to a coefficient of linear expansion of the chip substrate 21 of the semiconductor chip 20. For example, a coefficient of linear expansion of the encapsulation resin layer 60 may be a value which is higher than a coefficient of linear expansion of the chip substrate 21 of the semiconductor chip 20 and is similar to a coefficient of linear expansion (15 to 20 pm/° C.) of the mounting substrate 200. For example, a coefficient of linear expansion of the encapsulation resin layer 60 may be about 5 to about 15 ppm/° C. For example, a coefficient of linear expansion of the chip substrate 21 of the semiconductor chip 20 may be about 1 to about 3 ppm/° C.

The encapsulation resin layer 60 may be formed between the semiconductor chip 20 and the mounting substrate 200 and may thus function as a stress buffer layer which largely decreases stress occurring in the connection terminal part 80 due to a temperature change occurring between the semiconductor chip 20 and the mounting substrate 200.

When the semiconductor chip 20 includes an image sensor, the encapsulation resin layer 60 may include a light blocking part 61 which blocks light having a sensitivity wavelength of the image sensor.

In some embodiments, the encapsulation resin layer 60 may include a light blocking material such as carbon or a filler so as to obtain light blocking properties, and thus, all of the encapsulation resin layer 60 may function as the light blocking part 61.

In some embodiments, the encapsulation resin layer 60 may include, as the light blocking part 61, a film or a layer capable of obtaining light blocking properties to cover a portion or all of the encapsulation resin layer 60.

The semiconductor package 1 including an image sensor may decrease an adverse effect occurring in the image sensor due to stray light such as reflected light or scattering light, based on the encapsulation resin layer 60 including the light blocking part 61.

The connection terminal part 80 may include a conductive material such as a solder. The connection terminal part 80 may be formed to contact the exposure surface 52a of the second end portion 52 of the pillar electrode 50. In some embodiments, the connection terminal part 80 may not be formed in the second end portion 52 of the pillar electrode 50.

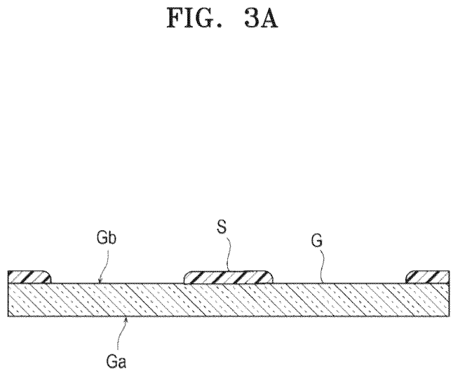

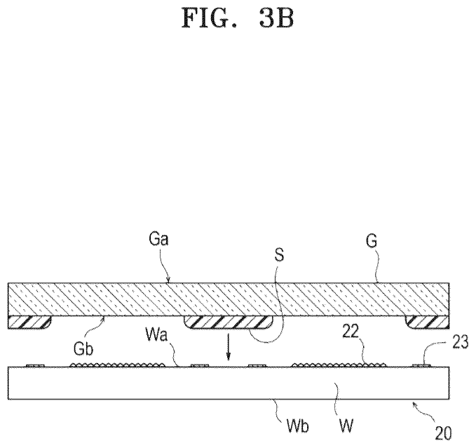

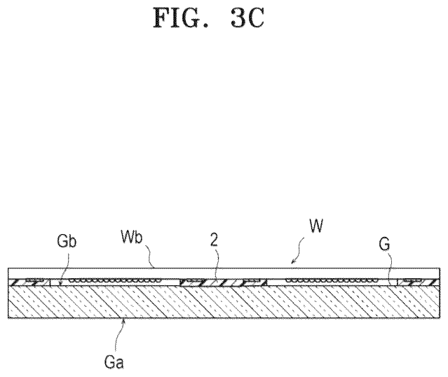

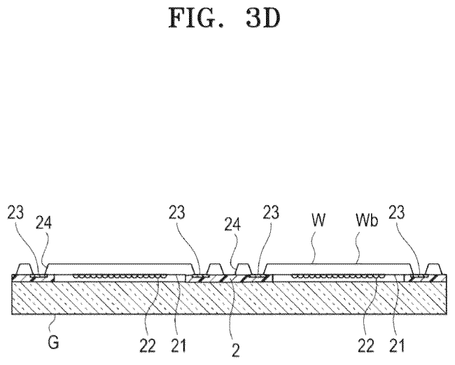

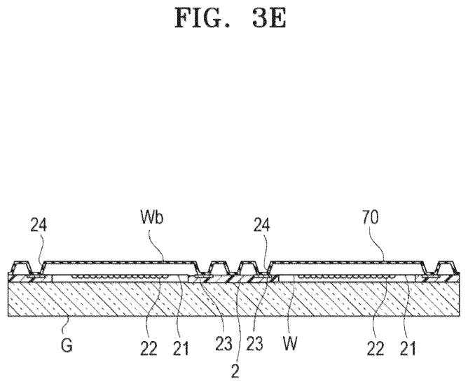

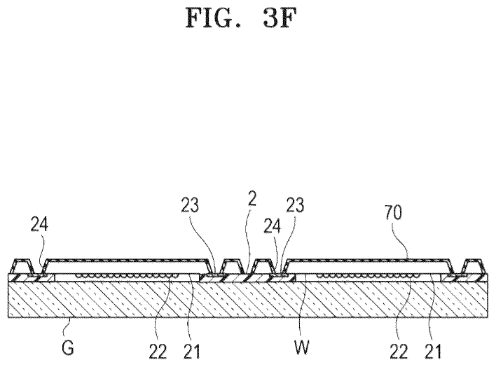

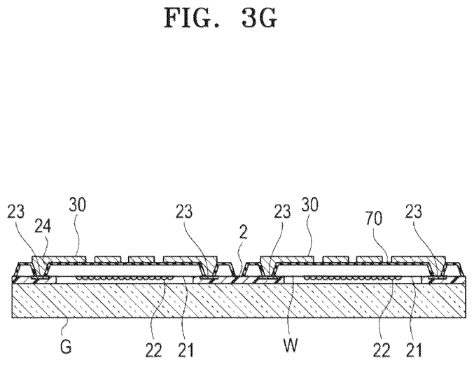

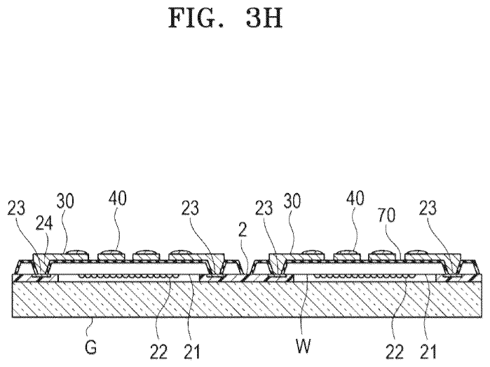

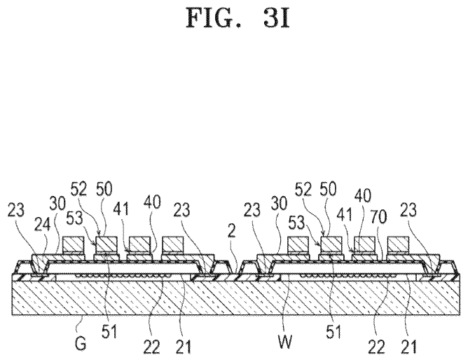

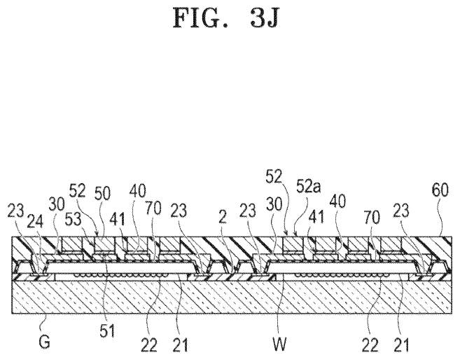

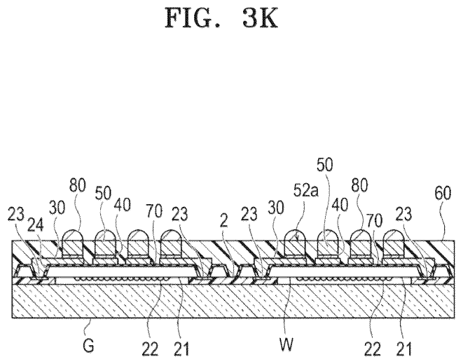

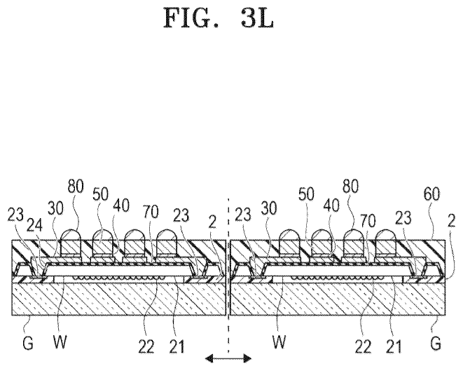

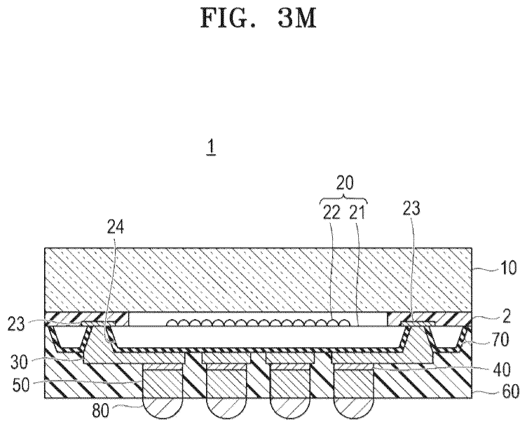

FIGS. 3A to 3L are cross-sectional views schematically illustrating a method of manufacturing a semiconductor package 1, according to one or more embodiments. In detail, FIGS. 3A to 3L illustrate configuration diagrams of processes (process one to process twelve) included in a manufacturing process of the semiconductor package 1.

The method of manufacturing the semiconductor package 1 will be described below with reference to FIGS. 3A to 3L. The method of manufacturing the semiconductor package 1 may include processes one to twelve described below. FIG. 3M is a cross-sectional view schematically illustrating the semiconductor package 1 manufactured by a method of manufacturing the semiconductor package 1, according to one or more embodiments.

Referring to FIG. 3A, in process one, a process of coating an encapsulant S functioning as the bonding part 2 on a second surface Gb, which is opposite to a first surface Ga, of a glass substrate G which is the transparent substrate 10 may be performed. The encapsulant S may be coated to include a boundary portion which is cut and is a periphery of an individual package.

Referring to FIG. 3B, in process two, a process of bonding the second surface Gb of the glass substrate G, on which the encapsulant S is coated, to a first surface Wa of a semiconductor wafer W which is a chip substrate 21 (see FIG. 3D) of the semiconductor chip 20, with facing each other, may be performed.

In the semiconductor wafer W, a microlens 22, an electrode 23, and each element configuring the other image sensor may be mounted in a light receiving region for each package of the first surface Wa. In process two, a bonding part 2 may be formed by curing the encapsulant S.

Referring to FIG. 3C, in process three, back grinding may be performed on the second surface Wb of the semiconductor wafer W so that the semiconductor wafer W has a thickness corresponding to a certain chip size.

Referring to FIG. 3D, in process four, a process of forming a through hole 24 from the second surface Wb of the semiconductor wafer W through etching may be performed. The through hole 24 may be formed by DRIE.

The through hole 24 may be formed at a boundary position of a package or a formation position of the electrode 23. As the through hole 24 is formed, a portion of the bonding part 2 of a boundary portion and a portion of the electrode 23 may be exposed at the outside.

Referring to FIG. 3E, in process five, a process of forming an insulation layer 70 on an entire surface of the second surface Wb of the semiconductor wafer W may be performed. The insulation layer 70 may be formed by a deposition process, a sputtering process, or a CVD process.

Referring to FIG. 3F, in process six, a process of removing the insulation layer 70 disposed on a bottom portion of the through hole 24 to expose a portion of the electrode 23 at the outside so as to enable an electrical connection of the electrode 23 may be performed. The insulation layer 70 may be removed through an etching process.

Referring to FIG. 3G, in process seven, a process of forming a wiring layer 30 on the insulation layer 70 may be performed. The wiring layer 30 may be formed to be electrically connected to the electrode 23 by using a photolithography process and a plating process.

Referring to FIG. 3H, in process eight, a process of coating a conductive paste to form a first conductive part 40 may be performed. The first conductive part 40 may be formed on the wiring layer 30 corresponding to a position at which a pillar electrode 50 (see FIG. 31) is to be formed. The first conductive part 40 may be formed by a screen printing process or an inkjet printing process in a state where a mask is formed in a region other than a formation position.

Referring to FIG. 31, in process nine, a process of placing a pillar electrode 50 on the first conductive part 40 may be performed. A placement process of the pillar electrode 50 may be similar to a ball mounting process. The placement process of the pillar electrode 50 may include a process of forming a mask in a region other than the first conductive part 40 so that the first conductive part 40 is exposed, a process of placing a copper pin from an opening portion of the mask to allow the copper pin to contact each first conductive part 40, while transferring a plurality of copper pins corresponding to the pillar electrode 50 on the mask, and a process of removing the mask and drying, firing, and curing the first conductive part 40. An end portion, contacting the first conductive part 40, of the pillar electrode 50 may be a first end portion 51.

Referring to FIG. 3J, in process ten, a process of forming an encapsulation resin layer 60 may be performed. The encapsulation resin layer 60 may be formed by coating resin including a nonconductive filler on epoxy resin and then performing a back grinding process to expose an exposure surface 52a of a second end portion 52 of the pillar electrode 50.

Therefore, the encapsulation resin layer 60 may be formed to cover the wiring layer 30 and a side surface of each of the first conductive part 40 and the pillar electrode 50 in a state where the second end portion 52 of the pillar electrode 50 is exposed.

Referring to FIG. 3K, in process eleven, a process of forming a connection terminal part 80 on the exposure surface 52a of the second end portion 52 of the pillar electrode 50 may be performed. The connection terminal part 80 may be formed by a ball mounting process or a screen printing process. In process eleven, a height position of a contact surface of the connection terminal part 80 on the mounting substrate 200 may be formed to be an almost equal position in a thickness direction of the semiconductor package 1 in terms of mounting easiness.

Referring to FIG. 3L, in process twelve, a process of cutting a certain number of semiconductor wafers W to individualize (singulation) the semiconductor package 1 may be performed.

Referring to FIG. 3M, the semiconductor package 1 manufactured through processes one to twelve described above may be seen.

Also, the method of manufacturing the semiconductor package 1 described above may include a process (for example, a process of performing cleaning) of performing other processing other than processes one to twelve, depending on the case.

Also, the method of manufacturing the semiconductor package 1 may be performed by appropriately changing a performance order of each process within a range where a configuration and a function of the semiconductor package 1 manufactured does not deviate from the gist of the disclosure.

Also, in the manufacturing method described above, the semiconductor package 1 may be configured so that the connection terminal part 80 is not formed in the second end portion 52 of the pillar electrode 50. In this case, processing of process eleven may be omitted.

The semiconductor package 1 according to one or more embodiments may be manufactured through appropriate modification as in each embodiment described below. Also, in describing each embodiment, a difference from the shape described above may be described, an element having the same function as another shape may be referred to by like reference numeral, and detailed descriptions may be omitted and may not be given. Also, a configuration, a member, and a use method may be the same as each shape. Additionally, in each embodiment, a desired element among elements described in each embodiment may be appropriately selected and may be combined with another shape, withing a range which does not deviate from the gist of the disclosure.

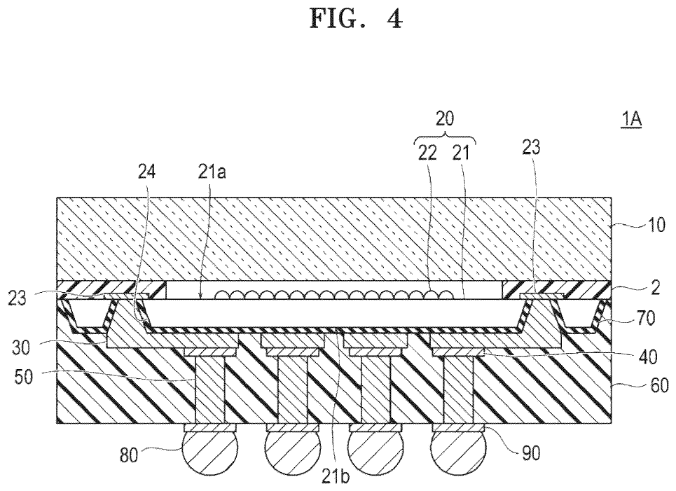

FIG. 4 is a cross-sectional view schematically illustrating a semiconductor package 1A according to embodiments.

Referring to FIG. 4, the semiconductor package 1A differs from other types of semiconductor packages in that a second conductive part 90 (second conductor) is formed in a second end portion 52 of a pillar electrode 50.

The second conductive part 90 may be disposed between the pillar electrode 50 and a connection terminal part 80 and may electrically connect the pillar electrode 50 to the connection terminal part 80.

The second conductive part 90 may include a conductive material, and for example, may include a material which includes, as a main component, copper such as a copper paste or copper plating. The second conductive part 90 may be formed by a screen printing process or an inkjet printing process in a state where a mask is formed in a region other than a formation position.

The second conductive part 90 may be formed to have an area which is greater than or equal to that of the exposure surface 52a of the second end portion 52 of the pillar electrode 50. For example, the second conductive part 90 may have a width which is greater than that of the second end portion 52 of the pillar electrode 50.

In some embodiments, in the semiconductor package 1A, a size of the connection terminal part 80 may be adjusted based on an area size of the second conductive part 90 when forming the connection terminal part 80 on the second conductive part 90.

In FIG. 4, the semiconductor package 1A may include the connection terminal part 80 formed on the second conductive part 90, but is not limited thereto and may not include the connection terminal part 80.

A process of forming the second conductive part 90 through the method of manufacturing the semiconductor package 1A may be performed between process ten illustrated in FIG. 3J and process eleven illustrated in FIG. 3K. For example, after the encapsulation resin layer 60 is formed in process ten, the second conductive part 90 may be formed on the exposure surface 52a of the second end portion 52 of the pillar electrode 50 exposed from the encapsulation resin layer 60.

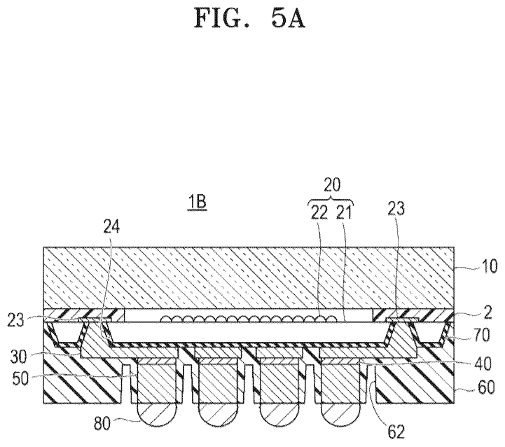

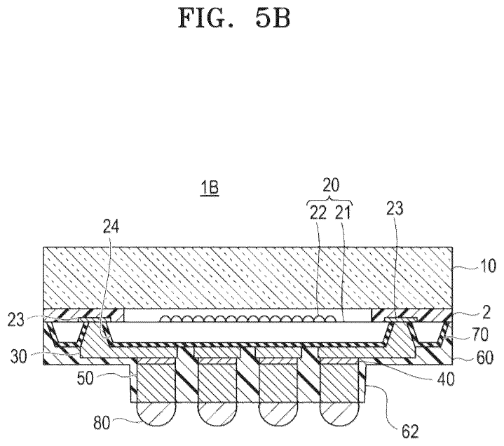

FIG. 5A is a cross-sectional view schematically illustrating a semiconductor package 1B according to embodiments. FIG. 5B is a cross-sectional view schematically illustrating the semiconductor package 1B according to embodiments.

Referring to FIGS. 5A and 5B, the semiconductor package 1B differs from other types of semiconductor packages in that a groove portion 62 is formed in an encapsulation resin layer 60.

The encapsulation resin layer 60 may include the groove portion 62. The groove portion 62 may pass through a portion of the encapsulation resin layer 60. For example, the groove portion 62 may extend from a lower surface of the encapsulation resin layer 60 to an inner portion of the encapsulation resin layer 60. The groove portion 62 may considerably decrease a strain (bending or the like) of a package caused by a temperature change or stress when connecting the encapsulation resin layer 60 to the connection terminal part 80.

For example, the groove portion 62 may be apart from a pillar electrode 50 in a horizontal direction. In some embodiments, as illustrated in FIG. 5A, the groove portion 62 may be disposed between pillar electrodes 50 adjacent to each other in a direction (a horizontal direction of the drawing) intersecting with a thickness direction of the semiconductor package 1B. In some embodiments, as illustrated in FIG. 5B, the groove portion 62 may have a shape where a portion of a periphery of the semiconductor package 1B is removed.

In some embodiments, the groove portion 62 illustrated in each of FIGS. 5A and 5B may be processed in shape by cutting a portion of the encapsulation resin layer 60 from a shape illustrated in FIG. 2 described above, and the encapsulation resin layer 60 may be formed to have a shape illustrated in FIGS. 5A and 5B.

Also, the groove portion 62 may be formed at a position for buffering stress applied to the encapsulation resin layer 60 at least. Also, when the groove portion 62 has a shape representing a stress buffer effect, the groove portion 62 is not limited to a formation position or a shape illustrated in FIG. 5A or 5B.

A process of forming the groove portion 62 through the method of manufacturing the semiconductor package 1B may be performed between process ten illustrated in FIG. 3J and process eleven illustrated in FIG. 3K. That is, after the encapsulation resin layer 60 is formed in process ten, the groove portion 62 may be formed by removing a portion of the encapsulation resin layer 60. In some embodiments, in a case where the encapsulation resin layer 60 is formed in a state where the groove portion 62 is previously formed, the removal process may not be needed.

As described above, the semiconductor packages 1, 1A, and 1B according to one or more embodiments may include the semiconductor chip 20 where the electrode 23 is formed on the first surface 21a which is a surface, on which light is incident, of the chip substrate 21, the through hole 24 which extends to the electrode 23 from the second surface 21b, which is opposite to the first surface 21a, of the chip substrate 21, the wiring layer 30 which is disposed on the second surface 21b of the chip substrate 21 and is electrically connected to the electrode 23 through the through hole 24, the pillar electrode 50 which is electrically connected to the wiring layer 30, and the first conductive part 40 which is disposed between the pillar electrode 50 and the wiring layer 30, the side surface 53 of the pillar electrode 50 and the side surface 41 of the first conductive part 40 may be covered by the encapsulation resin layer 60, and the first end portion 51, contacting the first conductive part 40, and the second end portion 52, which is opposite thereto, of the pillar electrode 50 may be exposed from the encapsulation resin layer 60.

Because the semiconductor package 1 includes the first conductive part 40 which is disposed between the wiring layer 30 and the pillar electrode 50 and the encapsulation resin layer 60 which is formed to cover the side surface 53 of the pillar electrode 50 and the side surface 41 of the first conductive part 40, stress occurring in the connection terminal part 80 due to a temperature change of when the semiconductor package 1 is mounted on the mounting substrate 200 may be considerably reduced. Accordingly, the semiconductor package 1 may be considerably enhanced in connection reliability of the connection terminal part 80.

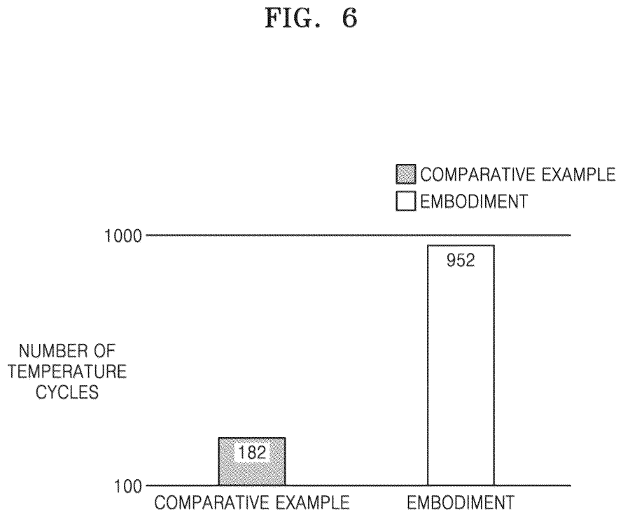

FIG. 6 is a graph showing a result of a solder lifetime simulation of each of one or more embodiments and a comparative example.

An effect of the disclosure may be described by using the following embodiment and comparative example with reference to FIG. 6. However, the scope of the disclosure is not limited to only the following embodiment.

In the following evaluation test, the connection reliability of a connection terminal part (hereinafter referred to as a solder) of a semiconductor package according to one or more embodiments has been evaluated based on a simulation result of a solder lifetime.

The evaluation test has been performed as follows. The evaluation test has used Marc2023 (the product of MSC Software Co., Ltd.) as structural analysis software. A lifetime simulation of a solder may be performed by, for example, a known method such as a method described in prior art reference (“lifetime prediction of a lead-free solder bonding part with heat wave” Kibo Technology-rating Open 2013-12 No.49 Ema Tetsuya Yamaha Motor Co., Ltd.).

The following condition has been set in a simulation. One or more embodiments has used, as a model, the semiconductor package according to one or more embodiments illustrated in FIG. 2, and the comparative example has used a semiconductor package of a general CSP as a model. Each model has used a ¼ model, based on symmetry. “¼ model” may be a modeling of a simulation and may denote that a simulation is performed on only ¼ of a package instead of all of the package under a horizontal and vertical symmetry condition. An element class has been set to a 20-node hexahedron. In a boundary condition, time dependence of a temperature has been set on symmetry restriction and all nodes. Also, in the time dependence of a temperature, an initial temperature has been set to 175° C. which is a curing temperature of a stress relief layer, and after being cooled at a room temperature (25° C.), a temperature cycle test condition of −55° C. to 125° C. has been set to a condition where 10 cycles are performed. In material physical properties, elastic physical properties having no temperature dependence have been set in a substrate, a semiconductor chip, a transparent substrate, a wiring layer, a first conductive layer, and a DAM agent, and viscoelasticity has been set in an encapsulation resin layer (potting resin). Also, plastic properties have been set in a solder.

A test has obtained a time-plastic deformation history of a node, where total plastic deformation is the maximum, from a simulation result so as to calculate a solder lifetime, extracted a plastic deformation of a 10th cycle therein, and set the extracted plastic deformation to a plastic deformation amplitude. The number of lifetime cycles of a solder has been obtained from the obtained plastic deformation amplitude and Coffin-Manson law. The number of lifetime cycles of a solder conforms with Coffin-Manson law.

An evaluation result is shown in FIG. 6. The evaluation result shown in FIG. 6 represents a prediction result of the number of temperature cycles of each of one or more embodiments and the comparative example. The prediction result of FIG. 6 represents that a solder lifetime increases as the number of temperature cycles increases and is high in solder connection reliability.

As shown in FIG. 6, in the comparative example, the number of temperature cycles is 182. On the other hand, in one or more embodiments, the number of temperature cycles is 952. Based on such a result, when a structure according to one or more embodiments is applied, it may be seen that a solder lifetime increases by about 5 times.

As described above, because a semiconductor package according to one or more embodiments includes a first conductive part disposed between a wiring layer of a semiconductor chip and a pillar electrode electrically connected thereto and an encapsulation resin layer covering a side surface of a pillar electrode and a side surface of the first conductive part, solder stress caused by a temperature change in package mounting may be reduced, and thus, solder connection reliability may increase.

While the inventive concept has been particularly shown and described with reference to embodiments thereof, it will be understood that various changes in form and details may be made therein without departing from the spirit and scope of the following claims.

What is claimed is:

1. A semiconductor package comprising:
a semiconductor chip comprising an electrode on a first surface, which is a light incident surface, of a substrate;
a through hole extending from a second surface of the substrate, which is opposite to the first surface of the substrate, to the electrode;
a wiring layer on the second surface and electrically connected to the electrode through the through hole;
a pillar electrode electrically connected to the wiring layer;
a first conductor between the pillar electrode and the wiring layer; and
a resin layer on a side surface of the pillar electrode and a side surface of the first conductor,
wherein a second end portion of the pillar electrode, which is opposite to a first end portion of the pillar electrode contacting the first conductor,, is exposed from the resin layer.

2. The semiconductor package of claim 1, wherein an elastic modulus of the first conductor is lower than an elastic modulus of the pillar electrode.

3. The semiconductor package of claim 1, further comprising:
a second conductor on an exposure surface of the second end portion of the pillar electrode and has an area greater than an area of the exposure surface.

4. The semiconductor package of claim 3, wherein the second conductor comprises copper as a main component.

5. The semiconductor package of claim 3, further comprising:
a connection terminal on the second conductor.

6. The semiconductor package of claim 1, further comprising:
a connection terminal on an exposure surface of the second end portion of the pillar electrode.

7. The semiconductor package of claim 1, wherein the pillar electrode comprises a metal pin.

8. The semiconductor package of claim 1, wherein the resin layer comprises a nonconductive filler.

9. The semiconductor package of claim 1, wherein a coefficient of linear expansion of the resin layer is greater than or equal to a coefficient of linear expansion of the substrate.

10. The semiconductor package of claim 1, wherein the first conductor comprises at least one of: a conductive paste, or a solder.

11. The semiconductor package of claim 1, wherein the resin layer comprises a groove portion in at least a portion of a periphery of the pillar electrode.

12. The semiconductor package of claim 1, wherein the semiconductor chip comprises an image sensor.

13. The semiconductor package of claim 12, wherein the resin layer comprises a light block configured to block light having a sensitivity wavelength of the image sensor.

14. A semiconductor package comprising:
a semiconductor chip comprising a substrate comprising:
a first surface;
a second surface opposite to the first surface; and
an electrode on the first surface;
a through hole extending from the second surface to the electrode;
a wiring layer on the second surface, in the through hole, and electrically connected to the electrode;
a first conductor on the wiring layer;
a pillar electrode on the first conductor and electrically connected to the wiring layer; and
a resin layer on the second surface of the substrate and around a side surface of the first conductor and a side surface of the pillar electrode,
wherein a coefficient of linear expansion of the resin layer is greater than or equal to a coefficient of linear expansion of the substrate.

15. The semiconductor package of claim 14,
wherein the coefficient of linear expansion of the resin layer is 5 ppm/° C. to 15 ppm/° C. and
wherein the coefficient of linear expansion of the substrate is 1 ppm/° C. to 3 ppm/° C.

16. The semiconductor package of claim 14, wherein a second end portion of the pillar electrode, opposite to a first end portion of the pillar electrode contacting the first conductor, is aligned with one surface of the resin layer, further comprising:
a second conductor on the second end portion of the pillar electrode and having a width greater than a width of the second end portion of the pillar electrode.

17. The semiconductor package of claim 14,
wherein the resin layer further comprises a groove portion passing through at least a portion of the resin layer, and
wherein the groove portion of the resin layer is apart from the pillar electrode.

18. The semiconductor package of claim 14, wherein an elastic modulus of the first conductor is lower than an elastic modulus of the pillar electrode.

19. A semiconductor package comprising:
a transparent substrate;
a semiconductor chip comprising a substrate comprising:
a first surface facing the transparent substrate;
a second surface opposite to the first surface; and
an electrode on the first surface;
a through hole extending from the second surface to the electrode;
a wiring layer on the second surface, in the through hole, and electrically connected to the electrode;
a first conductor on the wiring layer;
a pillar electrode on the first conductor and electrically connected to the wiring layer;
a resin layer on the second surface of the substrate of the semiconductor chip and around a side surface of the first conductor and a side surface of the pillar electrode; and
a connection terminal on a second end portion of the pillar electrode, opposite to a first end portion of the pillar electrode contacting the first conductor, wherein an elastic modulus of the first conductor is lower than an elastic modulus of the pillar electrode.

20. The semiconductor package of claim 19,
wherein a coefficient of linear expansion of the resin layer is greater than or equal to a coefficient of linear expansion of the substrate of the semiconductor chip, and
wherein the second end portion of the pillar electrode is exposed at an outer portion of the resin layer.
